(19) United States
(12) Patent Application Publication
(10) Pub. No.: US 2016/0124623 A1
(43) Pub. Date: May 5, 2016

(54) CONTROL SYSTEM FOR ONE OR MORE VEHICULAR ELECTRONIC SYSTEMS

(71) Applicant: HON HAI PRECISION INDUSTRY CO., LTD., New Taipei (TW)

(72) Inventor: JEN-TSORNG CHANG, New Taipei (TW)

(21) Appl. No.: 14/611,907

(22) Filed: Feb. 2, 2015

(30) Foreign Application Priority Data
Oct. 31, 2014 (CN) 201410600877.4

(51) Int. Cl. G06F 3/0484; B60K 35/00; G06F 3/0481; G06F 3/0488; G06F 3/041; G06F 3/0482

(52) U.S. Cl. CPC G06F 3/04847; G06F 3/0412; G06F 3/0482; G06F 3/04817; G06F 3/04883; B60K 35/00; B60K 2350/928

(57) ABSTRACT

A steering wheel with touch control for vehicular electronic systems is described. The touch control is on the steering wheel and includes a display portion and a touch sensitive portion, the touch sensitive portion overlying the display portion. An MCU electronically connects the at least one touch control with a plurality of vehicular electronic systems. When a driver touches a first part of the touch sensitive portion, the MCU causes the display portion to display icons relevant to controlling a first electronic system. When a driver touches a second part of the touch sensitive portion, the MCU causes the display portion to display icons relevant to controlling a second electronic system.

### FIELD

Generally, the present disclosure is related to the field of controlling various vehicular electronic systems. Particularly, the disclosure is related to steering wheels with touch controls for controlling the various vehicular electronic systems.

### BACKGROUND

Vehicles are often provided with one or more electronic control systems that the driver/user may need to manipulate while driving the vehicle. Manipulation and control of the systems have often required the driver to remove his eyes from viewing the road or path in the direction the vehicle is traveling.

This can be dangerous.

Accordingly, there is room for improvement within the art.

### BRIEF DESCRIPTION OF THE DRAWINGS

FIG. 1 depicts an exemplary embodiment of a steering wheel with touch control for vehicular electronic systems.

FIG. 2A is a block diagram of an exemplary embodiment of a steering wheel with touch control for vehicular electronic systems.

FIG. 2B is a block diagram of an exemplary embodiment of a steering wheel with touch control for vehicular electronic systems.

FIG. 3A is an exemplary embodiment of a touch control configured for controlling a variety of different vehicular electronic systems.

FIG. 3B depicts an exemplary embodiment of a touch control configured for controlling a variety of different vehicular electronic systems.

FIG. 3C depicts an exemplary embodiment of a touch control configured for controlling a variety of different vehicular electronic systems.

FIG. 3D depicts an exemplary embodiment of a touch control configured for controlling a variety of different vehicular electronic systems.

FIG. 4 depicts an exemplary structure for a touch control for use with the steering wheel with touch control for vehicular electronic systems.

FIG. 5A depicts a diagrammatic view of an exemplary touch sensitive film for use with the steering wheel with touch control for vehicular electronic systems.

FIG. 5B depicts a diagrammatic views of an exemplary touch sensitive film for use with the steering wheel with touch control for vehicular electronic systems.

FIG. 6 depicts a diagrammatic view of an exemplary touch control for use with the steering wheel with touch control for vehicular electronic systems.

FIG. 7 depicts a cross-sectional view along line 7-7 of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

The term “comprising” means “including, but not necessarily limited to”; it specifically indicates open-ended inclusion or membership in a so-described combination, group, series and the like.

Abbreviations used in this application are: MCU (master control unit), ITO (indium tin oxide), TFT (thin-film transistor), PET (polyethylene terephthalate) and EPD (electrophoretic display).

The present disclosure is described in relation to a steering wheel with touch control for vehicular electronic systems.

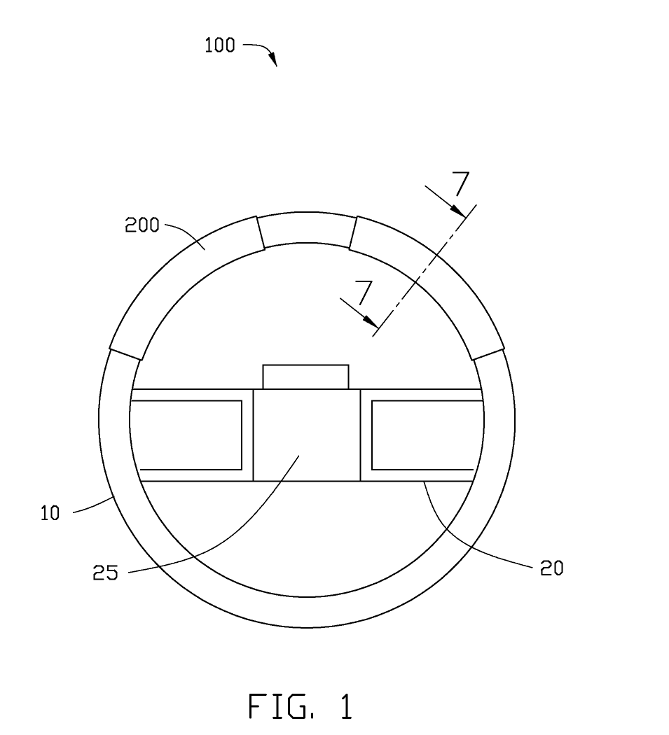

FIG. 1 depicts an exemplary embodiment of a steering wheel with touch control 100 for vehicular electronic systems. According to the exemplary embodiment, a vehicle (not shown) includes a steering wheel 10. Though the term “steering wheel” is generally used herein, such term should be construed to include other vehicular control members, such as: aircraft control yoke, ship's wheel, etc.). The steering wheel 10 may include a cross member 20 and an air bag 25.

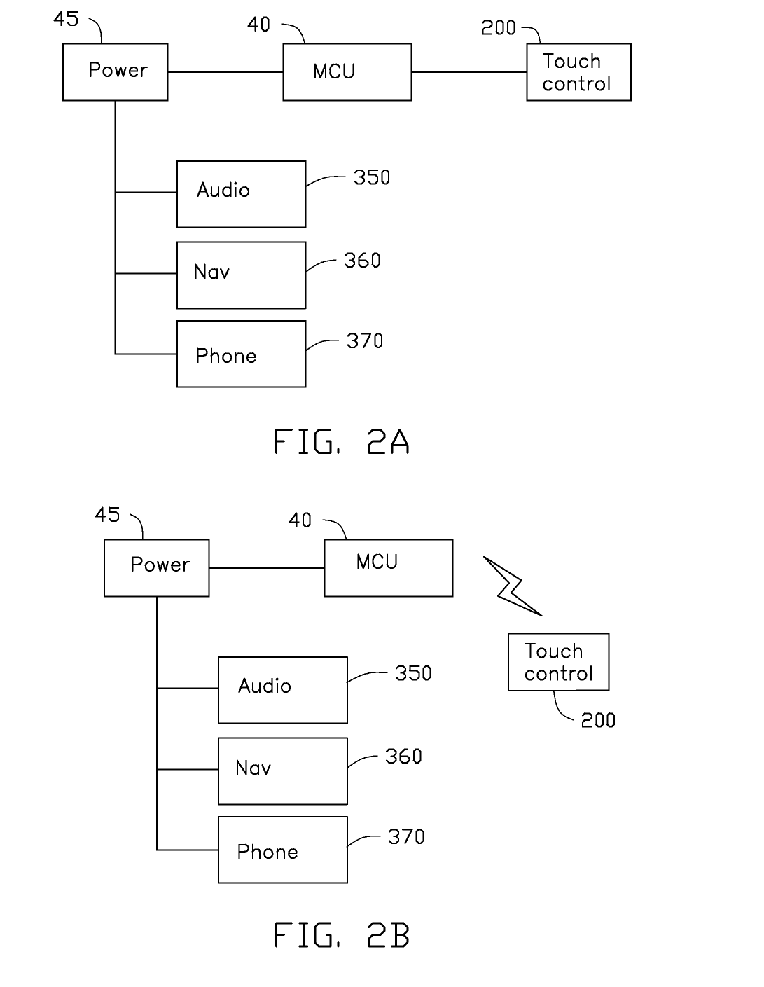

One or more touch controls 200 are positioned on the steering wheel 10. The touch controls 200 allow the vehicle driver to control one or more vehicular electronic systems associated with the vehicle without having to take their eyes off the road or path in which the vehicle is moving for an extended period of time. As examples, as shown in FIG. 2A and FIG. 2B, the electronic system controlled may be the vehicle's audio system 350, navigation system 360, communications system (mobile phone) 370, or any other electronic system.

Again referring to FIG. 2A and FIG. 2B, the steering wheel with touch control for vehicular electronic systems further comprises an MCU 40 electronically connected to: a power source 45, the touch control 200, and the vehicular electronic systems 350, 360, 370, to provide power and control signals to the touch control 200 and the vehicular electronic systems being controlled by the touch control.

MCU 40 is electronically connected to the touch control 200 and the electronic system by a wired (FIG. 2A) or wireless (FIG. 2B) connection. MCU 40 is physically attached to a portion of the steering wheel 10 or located hidden and nearby using the wireless connection.

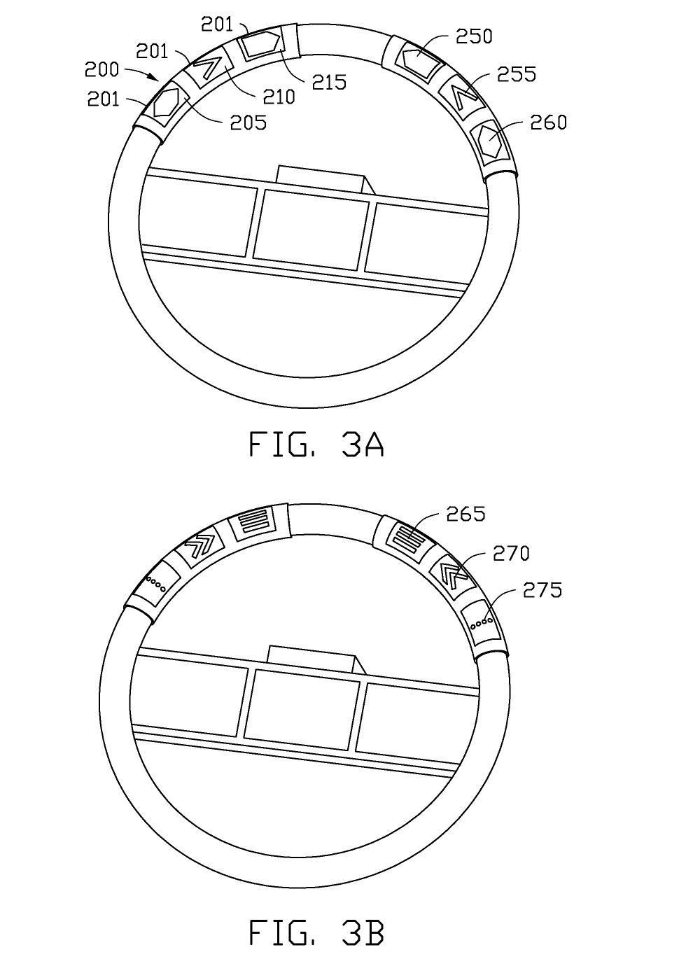

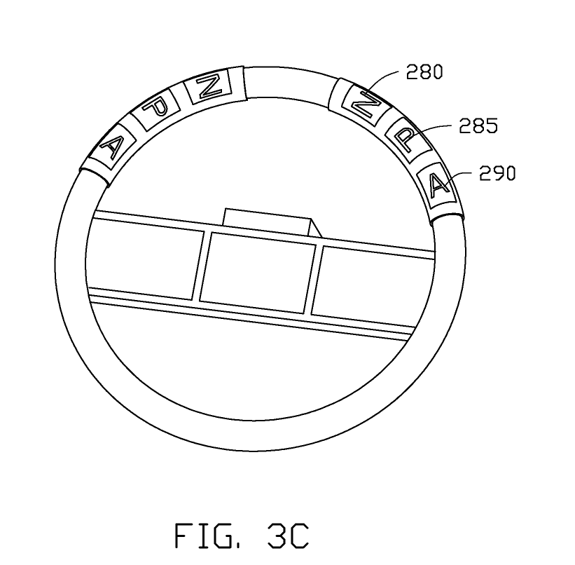

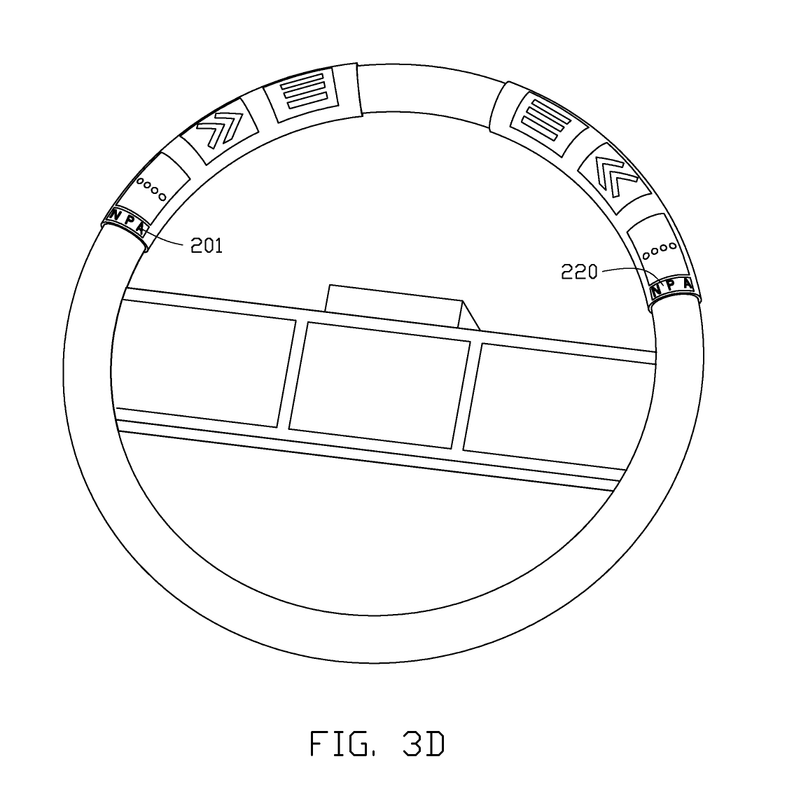

FIG. 3A depicts an exemplary embodiment of a touch control 200 configured for controlling a first electronic system. FIG. 3B depicts an exemplary embodiment of a touch control 200 configured for controlling a second electronic system. While only two exemplary vehicular electronic systems are shown, as previously mentioned any number of such vehicular electronic systems can be controlled by touch control 200.

As shown in FIG. 3A and FIG. 3B, each touch control 200 includes a plurality of touch sensitive portions 201, each touch sensitive portion 201 associated with one of a plurality of display portions 205, 210, 215. Each touch sensitive portion 201 is generally clear and covers one of the plurality of display portions 205, 210, 215 so that the covered display portions can still be seen.

In FIG. 3A, icons 250, 255, 260, relevant to controlling a first electronic system are displayed by display portions 201. In FIG. 3B, icons 265, 270, 275 relevant to controlling a second electronic system are displayed by display portions 201. In FIG. 3C, icons 280, 285, 290 representing menu icons for the various vehicular electronic systems that may be controlled can be displayed (i.e., N=Navigation/P=Phone/A=Audio). FIG. 3D depicts an exemplary embodiment including an additional touch sensitive portion 201 and display portion 220. The additional touch sensitive portion 201 and display portion 220 can display menu icons that may be used to give the user the ability to directly select the vehicular electronic system to be controlled from among all the available vehicular electronic systems.

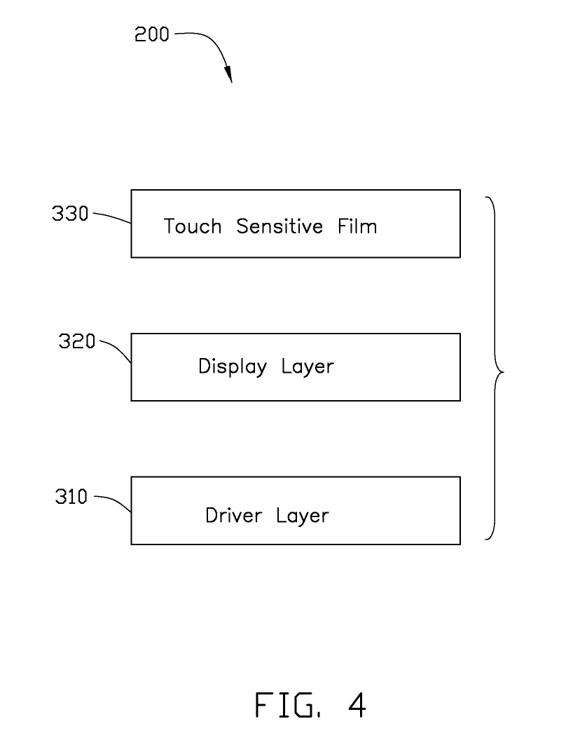

FIG. 4 shows the basic structure of each touch control 200. Each touch control 200 generally comprises three layers. The lowermost/bottom layer comprises a driver layer 310, such as a plastic TFT substrate layer 310. The middle layer comprises a display layer 320. Display layer 320 may comprise a combination plastic/ITO/EPD layer. The plastic TFT substrate layer 310 and the combination plastic ITO/EPD layer 320 form display portions 201. TFT substrate layer 310 acts as a driver circuit for causing ITO/EPD layer 320 to form and display graphics, such as text or icons. The topmost layer of each touch control 200 comprises a conventional touch sensitive film 330, such as a PET film.

FIG. 5A shows a close-up side view of PET touch sensitive film 330. The touch sensitive film 330 comprises a base substrate 335 with projecting rods 340 protruding from base substrate 335 (scale exaggerated for clarity). In an exemplary embodiment, rods 340 protrude from substrate 335 by approximately 5μ and 100μ. The diameter of rods 340 is between approximately 10μ and 200μ. FIG. 5B is a plan view of the structure shown in FIG. 5A.

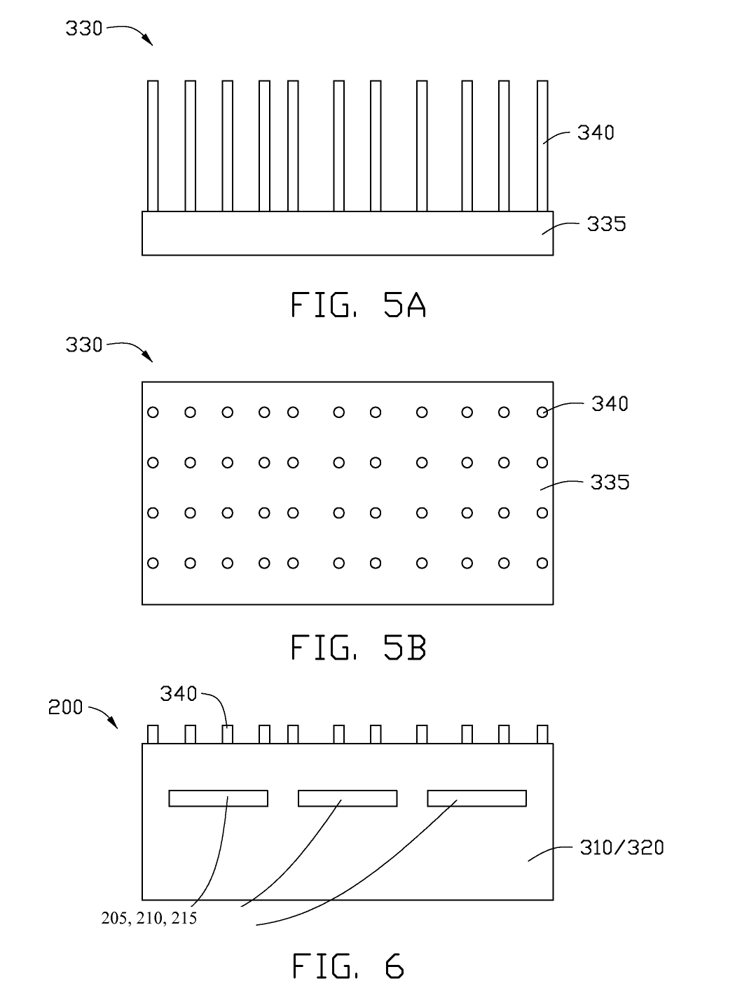

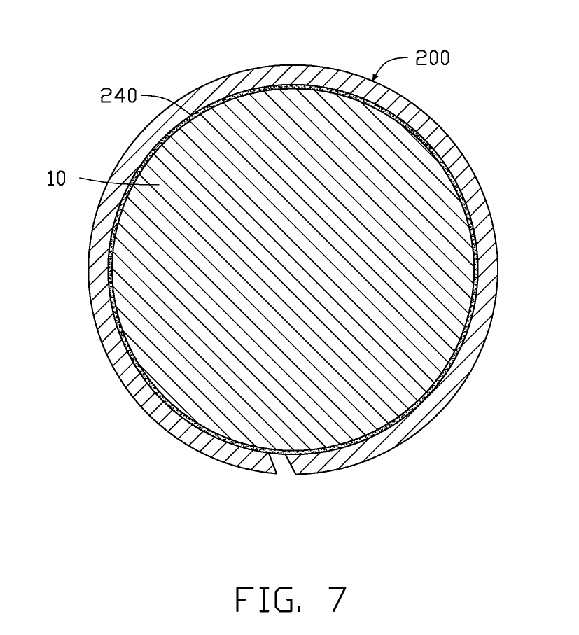

FIG. 6 shows an elevation view of a touch control 200. Display portions 205 are encased/encapsulated/enclosed by the TFT layer 310 and the ITO/EPD layer 320. The rods 340 of touch sensitive film 330 are exposed so that a user may interact therewith, as described below.

Finally, due to the materials described above and out of which each touch control 200 is manufactured, each touch control 200 is flexible. Therefore, as shown in FIG. 7, the touch control 200 can be wrapped around a portion of the steering wheel 10. Touch control 200 may be affixed to steering wheel 10 using an epoxy 240.

Having described the structure of an exemplary steering wheel with touch control for vehicular electronic systems, an exemplary mode of operation for the touch control will now be described.

A vehicle having a steering wheel or the like (aircraft control yoke, ship wheel, etc.) is provided with the touch control for controlling an electronic system associated with the vehicle. When the vehicle is started, display portions 205, 210, and 215 may automatically display icons associated with the last-used electronic control system, the most frequently used electronic control system or even display a menu of available electronic control systems. A user may then control a selected electronic system by manipulating the touch sensitive films of the touch controls that are positioned over the icons.

A user may at some time decide he wants to control a different electronic system. The user may then touch different areas of touch sensitive portions not associated with any particular icon (e.g., a blank area). The MCU will receive a signal that such an area is touched and interpret that signal as the user wanting to change from controlling one electronic system to controlling a different electronic system. Accordingly, the MCU will cause a different icon set to be displayed so that a different electronic system may be controlled. Through this process, a user can page through any number of different vehicular electronic systems. Additionally, as described relative to FIG. 3D, the user may touch any of menu icons displayed by an additional display portion so that the user may have direct access to any of the available vehicular electronic systems.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

What is claimed is:

1. A control system for one or more vehicular electronic systems, comprising:
a vehicular control member;
one or more touch controls mounted on the vehicular control member;
a master control unit electronically connected to the one or more touch controls and the one or more vehicular electronic systems; and
a display panel for displaying control data related to one of the one or more vehicular electronic systems;
wherein, the master control unit controls the one or more vehicular electronic systems based on input from the one or more touch controls;
wherein, a first portion of the one or more touch controls which control data is displayed on the display panel; and
wherein, a second portion of the one or more touch controls provides input to the master control unit to control the electronic system with control data displayed on the display panel.

2. The control system for one or more vehicular electronic systems of claim 1, further comprising a touch sensitive portion associated with a display portion that displays menu icons for each available electronic system, whereby a user can directly access control of a vehicular electronic system by touching the menu icon for the desired vehicular electronic system.

3. The control system for one or more vehicular electronic systems of claim 1, wherein at least one of the vehicular electronic systems comprises an audio system.

4. The control system for one or more vehicular electronic systems of claim 1, wherein at least one of the vehicular electronic systems comprises a navigation system.

5. The control system for one or more vehicular electronic systems of claim 1, wherein at least one of the vehicular electronic systems comprises a communication system.

6. The control system for one or more vehicular electronic systems of claim 1, wherein:
the display portion comprises a driver layer and a display layer; and
the touch sensitive portion comprises a touch sensitive film.

7. The control system for one or more vehicular electronic systems of claim 6, wherein:
the driver layer comprises a TFT driver layer and the display layer comprises an EPD layer.

8. The control system for one or more vehicular electronic systems of claim 7, wherein the EPD layer is combined with ITO.

9. The control system for one or more vehicular electronic systems of claim 6, wherein the touch sensitive film comprises a base substrate with projecting rods.

10. The control system for one or more vehicular electronic systems of claim 6, wherein the touch control is wrapped around a portion of the steering wheel.

11. The control system for one or more vehicular electronic systems of claim 1, wherein the touch control is flexible.

12. The control system for one or more vehicular electronic systems of claim 1, wherein the MCU is electronically connected to the touch control and the electronic system by a wired or wireless connection.

13. The control system for one or more vehicular electronic systems of claim 12, wherein the MCU is physically attached to a portion of the steering wheel.

14. A touch control for an electronic system, comprising:
a display portion; and
a touch sensitive portion, the touch sensitive portion overlying the display portion;
an MCU, the MCU electronically connected the at least one touch control with a plurality of vehicular electronic systems;
when a driver touches a first part of the touch sensitive portion, the MCU causes the display portion to display icons relevant to controlling a first electronic system; and
when a driver touches a second part of the touch sensitive portion, the MCU causes the display portion to display icons relevant to controlling a second electronic system.

15. The touch control of claim 14, wherein:
the display portion comprises a driver layer and a display layer; and
the touch sensitive portion comprises a touch sensitive film.

16. The touch control of claim 15, wherein:
the driver layer comprises a TFT driver layer and the display layer comprises an EPD layer.

17. The touch control of claim 16, wherein the EPD layer is combined with ITO.

18. The touch control of claim 15, wherein the touch sensitive film comprises a base substrate with projecting rods.

19. The touch control of claim 15, wherein the touch control is flexible.

20. The touch control of claim 14, wherein the touch control is wrapped around a portion of a steering wheel.
